(19) United States
(12) Patent Application Publication
(10) Pub. No.: US 2014/0023793 A1
(43) Pub. Date: Jan. 23, 2014

(54) METHOD FOR PRODUCING CONDUCTIVE FILM

(71) Applicant: FUJIFILM Corporation, Tokyo (JP)

(72) Inventors: Toyomi MATSUDA, Kanagawa (JP); Keio OKANO, Kanagawa (JP)

(73) Assignee: FUJIFILM Corporation, Tokyo (JP)

(21) Appl. No.: 14/034,048

(22) Filed: Sep. 23, 2013

Related U.S. Application Data
(62) Division of application No. 12/860,250, filed on Aug. 20, 2010.

(30) Foreign Application Priority Data
Sep. 29, 2009 (JP) 2009-225202

(51) Int. Cl. H05K 9/00

(52) U.S. Cl. CPC H05K 9/0081
USPC 427/532; 427/123

(57) ABSTRACT

A conductive film producing method according to the present invention contains a conductive metal portion forming step of forming a conductive metal portion containing a conductive substance and a binder on a support, and a vapor contact step of bringing the conductive metal portion into contact with a superheated vapor. This method may further contain a smoothing treatment step of smoothing the conductive metal portion, such that the smoothed conductive metal portion is brought into contact with the superheated vapor in the vapor contact step.

### CROSS-REFERENCE TO RELATED APPLICATIONS

This application is a division of application Ser. No. 12/860,250 filed on Aug. 20, 2010, which claims the benefit of priority from Japanese Patent Application No. 2009-225202 filed on Sep. 29, 2009, of which the contents are incorporated herein by reference.

### BACKGROUND OF THE INVENTION

1. Field of the Invention

The present invention relates to a method for producing a conductive film suitable for use as a light-transmitting electromagnetic-shielding film for various display devices, a transparent electrode for various electronic devices, a transparent planar heating element, etc.

2. Description of the Related Art

Recently, a material having a transparent substrate and a mesh-patterned conductive layer of a thin wire of metal or the like has been known as a conductive film suitable for use as a light-transmitting electromagnetic-shielding film for various display devices, a transparent electrode for various electronic devices, a transparent planar heating element, etc. A known method for producing such material contains the steps of exposing a photosensitive silver halide layer formed on a transparent substrate in a pattern to form a patterned developed silver, and subjecting the developed silver to a plating treatment to form a patterned conductive layer (see Japanese Laid-Open Patent Publication No. 2004-221564, etc.).

The surface resistance of the conductive film prepared from such a photosensitive material containing a silver salt (particularly a silver halide) can be sufficiently lowered by a smoothing treatment using a calender roll. Furthermore, the method is advantageously capable of forming a metallic silver portion with a desired pattern and uniform shape, thereby improving the conductive film productivity (see Japanese Laid-Open Patent Publication No. 2008-251417, etc.).

Also, there has been proposed a process for producing a conductive film having an improved conductivity by bringing a conductive metal portion formed on a support into contact with a vapor (see Japanese Laid-Open Patent Publication No. 2008-277249). This patent document describes the use of the vapor at 100° C. to 140° C.

Such a vapor can be in the state of a superheated vapor as well as a saturated vapor. For example, the superheated vapor is used in Japanese Laid-Open Patent Publication Nos. 2008-249817, 2009-086343, and 09-502252 (PCT Application), etc.

Japanese Laid-Open Patent Publication No. 2008-249817 describes a method for making a positive photosensitive planographic printing plate comprising a base having formed thereon in this order an undercoat layer and an image recording layer, wherein the undercoat layer is obtained by applying an undercoat layer solution containing a solvent and an acrylic resin having an alkali-soluble group, followed by drying the coating, and the image recording layer comprises a novolac resin and infrared absorbing agent. In this method, the applied undercoat layer solution is dried in an undercoat layer drying step which comprises a vapor-containing hot air drying step using vapor-containing hot air having a temperature of 90° C. to 200° C. and a relative humidity of 5% to 70%.

Japanese Laid-Open Patent Publication No. 2009-086343 describes a method containing a step of forming a photosensitive layer on a substrate, a step of coating the photosensitive layer with an overcoat layer, a first drying step of applying a hot air to the overcoat layer, and a second drying step of applying a hot air and a superheated vapor to the overcoat layer after the first drying step.

Japanese Laid-Open Patent Publication No. 09-502252 (PCT Application) describes a method for at least partly drying moist materials in a drying enclosure using a superheated vapor.

However, the above patent documents do not describe the use of the superheated vapor or pressurized vapor (pressurized saturated vapor) for producing a conductive film suitable as a light-transmitting electromagnetic-shielding film for various display devices, a transparent electrode for various electronic devices, a transparent planar heating element, etc.

### SUMMARY OF THE INVENTION

In view of the above problems, an object of the present invention is to provide a method for producing a conductive film, which is capable of improving the conductivity of the conductive film by utilizing a pressurized vapor (a pressurized saturated vapor) when producing a conductive film suitable for use as a light-transmitting electromagnetic-shielding film for various display devices, a transparent electrode for various electronic devices, a transparent planar heating element, etc.

Another object of the present invention is to provide a method for producing a conducive film, which is capable of improving the conductivity of the conductive film by utilizing a superheated vapor when producing a conductive film suitable for use as a light-transmitting electromagnetic-shielding film for various display devices, a transparent electrode for various electronic devices, a transparent planar heating element, etc.

[1] A method for producing a conductive film according to a first aspect of the present invention, comprising a conductive metal portion forming step of forming a conductive metal portion containing a conductive substance and a binder on a support, a smoothing treatment step of smoothing the conductive metal portion, and a vapor contact step of bringing the smoothed conductive metal portion into contact with a saturated vapor (a pressurized vapor) at a pressure higher than 0.1 MPa, wherein the saturated vapor has an absolute pressure of 101 to 361 kPaA.

[2] A method according to the first aspect, wherein the smoothed conductive metal portion is brought into contact with the pressurized vapor for 5 minutes or less.

[3] A method according to the first aspect, wherein the smoothed conductive metal portion is brought into contact with the pressurized vapor for 20 to 120 seconds.

[4] A method for producing a conductive film according to a second aspect of the present invention, comprising a conductive metal portion forming step of forming a conductive metal portion containing a conductive substance and a binder on a support, and a vapor contact step of bringing the conductive metal portion into contact with a superheated vapor.

[5] A method according to the second aspect, wherein the superheated vapor has a temperature of 100° C. to 160° C. at 1 atm.

[6] A method according to the second aspect, wherein the support comprises a polyethylene terephthalate (PET).

[7] A method according to the second aspect, wherein the superheated vapor has a temperature of 100° C. to 125° C. at 1 atm.

[8] A method according to the second aspect, wherein the conductive metal portion is brought into contact with the superheated vapor for 5 minutes or less.

[9] A method according to the second aspect, wherein the conductive metal portion is brought into contact with the superheated vapor for 4 to 120 seconds.

[10] A method according to the second aspect, wherein the superheated vapor is supplied at an amount of 500 to 600 g/m³.

[11] A method according to the second aspect, further comprising a smoothing treatment step of smoothing the conductive metal portion, wherein in the vapor contact step, the smoothed conductive metal portion is brought into contact with the superheated vapor.

[12] A method according to the first and second aspect, wherein in the conductive metal portion forming step, an emulsion layer containing a silver salt is formed on the support to prepare a photosensitive material, and thereafter the photosensitive material is exposed and developed to form the conductive metal portion on the support.

[13] A method according to the first and second aspect, wherein the emulsion layer has a silver/binder volume ratio of 1/1 or more.

[14] A method according to the first and second aspect, wherein in the conductive metal portion forming step, a paste containing the conductive substance and the binder is printed on the support to form the conductive metal portion on the support.

[15] A method according to the first and second aspect, wherein in the smoothing treatment step, the conductive metal portion is smoothed under a line pressure of 1960 N/cm (200 kgf/cm) or more.

As described above, in the conductive film producing method of the present invention, a conductive film suitable for use as a light-transmitting electromagnetic-shielding film for various display devices, a transparent electrode for various electronic devices, a transparent planar heating element, etc. can be produced with an improved conductivity by using a superheated vapor or a pressurized vapor (a pressurized saturated vapor).

The above and other objects, features and advantages of the present invention will become more apparent from the following description when taken in conjunction with the accompanying drawings in which preferred embodiments of the present invention is shown by way of illustrative example.

### BRIEF DESCRIPTION OF THE DRAWINGS

FIG. 1 is a structural view showing an example of a first drying apparatus for use in a first treatment using a superheated vapor; and

FIG. 2 is a structural view showing an example of a second drying apparatus for use in a second treatment using a pressurized vapor.

### DESCRIPTION OF THE PREFERRED EMBODIMENTS

The conductive film producing method of the present invention will be described below. The conductive film produced by the method of the present invention can be used in a defroster (defrosting device), a window glass, etc. for a vehicle, and be used as a heating sheet generating heat by flowing an electric current, an electrode for a touch panel, an inorganic EL device, an organic EL device, or a solar cell, or a printed board. It should be noted that, in this description, a numeric range of “A to B” includes both the numeric values A and B as the lower limit and upper limit values.

### <Photosensitive Material for Conductive Film Production>

### [Support]

The support of the photosensitive material used in the production method of the present invention may be a plastic film, a plastic plate, a glass plate, etc. Examples of materials for the plastic film and the plastic plate include polyesters such as polyethylene terephthalates (PET) and polyethylene naphthalates; polyolefins such as polyethylenes (PE), polypropylenes (PP), polystyrenes, and EVA; vinyl resins such as polyvinyl chlorides and polyvinylidene chlorides; polyether ether ketones (PEEK); polysulfones (PSF); polyether sulfones (PES); polycarbonates (PC); polyamides; polyimides; acrylic resins; and triacetyl celluloses (TAC).

### [Silver Salt-containing Layer]

The photosensitive material used in the production method of the present invention has the support and thereon the emulsion layer containing the silver salt (the silver salt-containing layer) as a light sensor. The silver salt-containing layer may contain a binder, a solvent, etc. in addition to the silver salt. Unless some question arises, the emulsion layer containing the silver salt (or the silver salt-containing layer) may be simply referred to as the emulsion layer.

The emulsion layer may contain a dye, a binder, a solvent, etc. if necessary in addition to the silver salt. Each component in the emulsion layer will be described below.

### <Dye>

The photosensitive material may contain a dye in at least the emulsion layer. The dye is used in the emulsion layer as a filter dye or for a purpose of irradiation prevention, etc. The dye may be a solid dispersion dye. Preferred examples of the dyes useful in the present invention are described in Japanese Laid-Open Patent Publication No. 2008-251417, and therefore the explanation of the examples is herein omitted. The mass ratio of the dye to the total solid contents in the emulsion layer is preferably 0.01% to 10% by mass, more preferably 0.1% to 5% by mass, in view of effect such as the irradiation prevention effect and the sensitivity reduction due to the excess addition.

### <Silver Salt>

The silver salt used in the present invention may be an inorganic silver salt such as a silver halide or an organic silver salt such as silver acetate. In the present invention, the silver halide is preferred because of its excellent light sensing property.

The silver halide, preferably used in the present invention, will be described below.

In the present invention, the silver halide excellent in the light sensing property is preferred. Silver halide technologies for photographic silver salt films, photographic papers, print engraving films, emulsion masks for photomasking, and the like may be utilized in the present invention.

The silver halide may contain a halogen element of chlorine, bromine, iodine, or fluorine, and may contain a combination of the elements. For example, the silver halide preferably contains AgCl, AgBr, or AgI, more preferably contains AgBr or AgCl, as a main component. The silver halide may contain silver chlorobromide, silver iodochlorobromide, or silver iodobromide. The silver halide is more preferably silver chlorobromide, silver bromide, silver iodochlorobromide, or silver iodobromide, most preferably silver chlorobromide or silver iodochlorobromide having a silver chloride content of 50 mol % or more.

The silver halide may be in the state of solid particles. The average particle size of the silver halide particles is preferably 0.1 to 1000 nm (1 μm), more preferably 0.1 to 100 nm, further preferably 1 to 50 nm, in spherical equivalent diameter, in view of the image quality of the patterned metallic silver layer formed after the exposure and development. The spherical equivalent diameter of the silver halide particle means a diameter of a spherical particle having the same volume as the silver halide particle.

The silver halide emulsion, used as a coating liquid for the emulsion layer in the present invention, may be prepared by a method described in P. Glafkides, “Chimie et Physique Photographique”, Paul Montel, 1967, G. F. Dufin, “Photographic Emulsion Chemistry”, The Forcal Press, 1966, V. L. Zelikman, et al., “Making and Coating Photographic Emulsion”, The Forcal Press, 1964, etc.

### <Binder>

A binder may be used in the emulsion layer to uniformly disperse the silver salt particles and to help the emulsion layer adhere to the support. In the present invention, though the binder may contain a water-insoluble polymer and a water-soluble polymer, it is preferred that the binder has a high content of a water-soluble component that can be removed by dipping in a hot water or bringing into contact with a water vapor as described hereinafter.

Examples of the binders include gelatins, carrageenans, polyvinyl alcohols (PVA), polyvinyl pyrolidones (PVP), polysaccharides such as starches, celluloses and derivatives thereof, polyethylene oxides, polysaccharides, polyvinylamines, chitosans, polylysines, polyacrylic acids, polyalginic acids, polyhyaluronic acids, and carboxycelluloses. The binders show a neutral, anionic, or cationic property due to ionicity of a functional group.

The binder preferably comprises a gelatin. The gelatin may be a lime-treated gelatin or an acid-treated gelatin, and may be a hydrolyzed gelatin, an enzymatically decomposed gelatin, or a gelatin having a modified amino or carboxyl group (such as a phthalated gelatin or an acetylated gelatin). The gelatin used in the preparation of the silver salt is preferably such that the positive charge of the amino group is converted to the uncharged or negatively charged state. It is further preferably to use the phthalated gelatin additionally.

The amount of the binder in the emulsion layer is not particularly limited, and may be appropriately selected to obtain sufficient dispersion and adhesion properties. The volume ratio of silver/binder in the emulsion layer is preferably 1/1 or more, more preferably 1.5/1 or more, further preferably 2/1 or more. The upper limit of the silver/binder volume ratio is preferably 20/1, more preferably 10/1. The silver/binder volume ratio can be obtained by converting the weight ratio of the silver halide material to the binder to the weight ratio of the silver to the binder, and by further converting the weight ratio of the silver to the binder to the volume ratio of the silver to the binder.

### <Solvent>

The solvent used for forming the emulsion layer is not particularly limited, and examples thereof include water, organic solvents (e.g. alcohols such as methanol, ketones such as acetone, amides such as formamide, sulfoxides such as dimethyl sulfoxide, esters such as ethyl acetate, ethers), ionic liquids, and mixtures thereof. In the present invention, the mass ratio of the solvent to the total of the silver salt, the binder, and the like in the emulsion layer is 30% to 90% by mass, preferably 50% to 80% by mass.

### [Non-photosensitive Intermediate Layer]

A non-photosensitive intermediate layer may contain a gelatin or a combination of a gelatin and an SBR. Further the layer may contain an additive such as a crosslinking agent or a surfactant.

### [Other Layers]

A protective layer may be formed on the emulsion layer. The protective layer used in the present invention comprises a binder such as a gelatin or a macromolecule, and is formed on the photosensitive emulsion layer to improve the scratch prevention or mechanical property. The thickness of the protective layer is preferably 0.3 μm or less. The method of applying or forming the protective layer is not particularly limited, and may be appropriately selected from known coating methods.

### <Conductive Film Producing Method>

The method for producing the conductive film using the above photosensitive material will be described below.

In the conductive film producing method of the present invention, first the photosensitive material comprising the support and thereon the silver salt-containing emulsion layer is exposed and developed. Then, the metallic silver portion formed by the development is subjected to the smoothing treatment such as a calender treatment. In the formation of the metallic silver portion, a light-transmitting portion or an insulating portion may be formed in addition to the metallic silver portion, or alternatively the metallic silver portion may be formed on the entire film surface by entire surface exposure. In the conductive film produced by the method of the present invention, the metal portion may be formed on the support by pattern exposure. In the pattern exposure, a scanning exposure method or a surface exposure method may be used. The metallic silver portion may be formed in an exposed area or an unexposed area.

The pattern shape details may be appropriately selected depending on the intended use. For example, the pattern may be a mesh pattern for producing an electromagnetic-shielding film or a wiring pattern for producing a printed board.

The conductive film producing method of the present invention includes the following three embodiments, different in the photosensitive materials and development treatments.

(1) Embodiment comprising subjecting a photosensitive black-and-white silver halide material free of physical development nuclei to a chemical or thermal development, to form the metallic silver portion on the photosensitive material.
(2) Embodiment comprising subjecting a photosensitive black-and-white silver halide material having a silver halide emulsion layer containing a physical development nucleus to a solution physical development, to form the metallic silver portion on the material.
(3) Embodiment comprising subjecting a stack of a photosensitive black-and-white silver halide material free of physical development nuclei and an image-receiving sheet having a non-photosensitive layer containing a physical development nucleus to a diffusion transfer development, to form the metallic silver portion on the non-photosensitive image-receiving sheet.

A negative development treatment or a reversal development treatment can be used in the embodiments. In the diffusion transfer development, the negative development treatment can be carried out using an auto-positive photosensitive material.

The chemical development, thermal development, solution physical development, and diffusion transfer development have the meanings generally known in the art, and are explained in common photographic chemistry texts such as Shin-ichi Kikuchi, “Shashin Kagaku (Photographic Chemistry)”, Kyoritsu Shuppan Co., Ltd. and C. E. K. Mees, “The Theory of Photographic Process, 4th ed.”

### [Exposure]

In the production method of the present invention, the silver salt-containing layer formed on the support is exposed. The layer may be exposed using an electromagnetic wave. For example, a light (such as a visible light or an ultraviolet light) or a radiation ray (such as an X-ray) may be used to generate the electromagnetic wave. The exposure may be carried out using a light source having a wavelength distribution or a specific wavelength. The irradiation light may be applied in a mesh pattern for producing an electromagnetic-shielding film or in a wiring pattern for producing a printed board.

### [Development Treatment]

In the production method of the present invention, the silver salt-containing layer is subjected to a development treatment after the exposure. Common development treatment technologies for photographic silver salt films, photographic papers, print engraving films, emulsion masks for photomasking, and the like may be used in the present invention. A developer for the development treatment is not particularly limited, and may be a PQ developer, an MQ developer, an MAA developer, etc. Examples of commercially available developers usable in the present invention include CN-16, CR-56, CP45X, FD-3, and PAPITOL available from FUJIFILM Corporation; C-41, E-6, RA-4, Dsd-19, and D-72 available from Eastman Kodak Company; and developers contained in kits thereof. The developer may be a lith developer such as D85 available from Eastman Kodak Company.

In the production method of the present invention, by the exposure and development treatments, the metallic silver portion is formed in the exposed area, and the light-transmitting portion to be hereinafter described is formed in the unexposed area. If necessary, the conductivity of the film may be further increased by water-washing the sample to remove the binder following the development treatment. In the present invention, the development, fixation, and water washing are preferably carried out at 25° C. or lower.

In the production method of the present invention, the development process may include a fixation treatment for removing the silver salt in the unexposed area to stabilize the material. Common fixation treatment technologies for photographic silver salt films, photographic papers, print engraving films, emulsion masks for photomasking, and the like may be used in the present invention.

The developer for the development treatment may contain an image quality improver for improving the image quality. Examples of the image quality improvers include nitrogen-containing heterocyclic compounds such as benzotriazole. Particularly a polyethylene glycol is preferably used for the lith developer.

The mass ratio of the metallic silver contained in the exposed area after the development to the silver contained in this area before the exposure is preferably 50% or more, more preferably 80% or more by mass. When the mass ratio is 50% by mass or more, a high conductivity can be easily achieved.

After the development treatment, the metallic silver portion in the exposed area contains the silver and a non-conductive macromolecule, and the volume ratio of silver/non-conductive macromolecule is preferably 1/1 or more, more preferably 1.5/1 or more, further preferably 2/1 or more, particularly preferably 3/1 or more. The upper limit of the silver/non-conductive macromolecule volume ratio is preferably 20/1, more preferably 10/1. The silver/non-conductive macromolecule volume ratio may be determined from the cross sectional area ratio between the silver portion and the non-conductive macromolecule which is obtained by cross-sectional observation of the metallic silver portion.

In the present invention, a tone (gradation) obtained by the development is preferably more than 4.0, though not particularly restrictive. When the tone after the development is more than 4.0, the conductivity of the conductive metal portion can be increased while maintaining high transparency of the light-transmitting portion. For example, the tone of 4.0 or more can be achieved by doping with rhodium or iridium ion.

### [Oxidation Treatment]

In the production method of the present invention, the metallic silver portion formed by the development is preferably subjected to an oxidation treatment. For example, by the oxidation treatment, a small amount of a metal deposited on the light-transmitting portion can be removed, so that the transmittance of the light-transmitting portion can be increased to approximately 100%.

For example, the oxidation treatment may be carried out by a known method using an oxidant such as Fe (III) ion. The oxidation treatment may be carried out after the exposure and development treatments of the silver salt-containing layer.

In the present invention, the metallic silver portion may be treated with a Pd-containing solution after the exposure and development treatments. The Pd may be in the state of divalent palladium ion or metal palladium. A black color of the metallic silver portion can be prevented from changing with time by this treatment.

In the production method of the present invention, the mesh metallic silver portion having particular line width, opening ratio, and silver content is formed directly on the support by the exposure and development treatments, and thereby can exhibit a satisfactory surface resistivity. Therefore, it is unnecessary to subject the metallic silver portion to further physical development and/or plating to increase the conductivity. Thus, in the present invention, the light-transmitting conductive film can be produced by the simple process.

As described above, the light-transmitting conductive film according to the present invention can be used in a defroster (defrosting device), a window glass, etc. for a vehicle, a heating sheet for heat generation under an electric current, an electrode for a touch panel, an inorganic EL device, an organic EL device, or a solar cell, or a printed board.

### [Reduction Treatment]

A desired high-conductive film can be obtained by dipping the photosensitive material in an aqueous reducing solution after the development treatment. The aqueous reducing solution may be an aqueous solution of sodium sulfite, hydroquinone, p-phenylenediamine, oxalic acid, etc. The aqueous solution preferably has a pH of 10 or more.

### [Another Method for Forming Conductive Metal Portion]

Though the conductive metal portion is formed on the support by forming the silver salt-containing emulsion layer on the support to prepare the photosensitive material and by exposing and developing the prepared photosensitive material in the above embodiment, the conductive metal portion may be formed on the support as follows.

That is, the conductive metal portion may be formed by printing a paste containing the conductive substance (such as silver) and the binder onto the support. Alternatively, the conductive metal portion (a thin metal film) may be printed on the support by using a screen printing plate or a gravure printing plate.

### [Smoothing Treatment]

In the production method of the present invention, the metallic silver portion (the entire-surface metallic silver portion, patterned metal mesh portion, or patterned metal wiring portion) is subjected to the smoothing treatment after the development. The conductivity of the metallic silver portion can be significantly increased by the smoothing treatment. When the areas of the metallic silver portion and the light-transmitting portion are appropriately designed, the resultant conductive film can be suitable for use as a light-transmitting electromagnetic-shielding film having a high electromagnetic-shielding property, a high light transmittability, and a black mesh portion, as a transparent electrode for various electronic devices, as a transparent planar heating element, etc.

The smoothing treatment may be carried out using a calender roll unit. The calender roll unit generally has a pair of rolls. The smoothing treatment using the calender roll unit is hereinafter referred to as the calender treatment.

The roll used in the calender treatment may be composed of a metal or a plastic such as an epoxy, a polyimide, a polyamide, or a polyimide-amide. Particularly in a case where the photosensitive material has the emulsion layer on both sides, it is preferably treated with a pair of the metal rolls. In a case where the photosensitive material has the emulsion layer only on one side, it may be treated by using the metal roll and the plastic roll in combination in view of preventing wrinkling. The lower limit of the line pressure is preferably 1960 N/cm (200 kgf/cm, corresponding to a surface pressure of 699.4 kgf/cm²) or more, more preferably 2940 N/cm (300 kgf/cm, corresponding to a surface pressure of 935.8 kgf/cm²) or more. The upper limit of the line pressure is 6860 N/cm (700 kgf/cm) or less.

The temperature, at which the smoothing treatment is carried out using typically the calender roll unit, is preferably 10° C. (without temperature control) to 100° C. Though the preferred temperature range is different depending on the density and shape of the mesh or wiring pattern of the metal, the type of the binder, etc., in general the temperature is more preferably 10° C. (without temperature control) to 50° C.

[Treatment with Vapor Contact]

In the production method of the present invention, the conductive metal portion is brought into contact with a vapor in the vapor contact step after the smoothing treatment. In the vapor contact step, the smoothed conductive metal portion may be brought into contact with the superheated vapor (a first treatment) or with the pressurized vapor (pressurized saturated vapor) (a second treatment). The conductivity and transparency can be easily improved in a short time by this step. It is considered that the water-soluble binder is partly removed in this step, whereby binding sites between the metal substances (the conductive substances) are increased.

<First Treatment using Superheated Vapor>

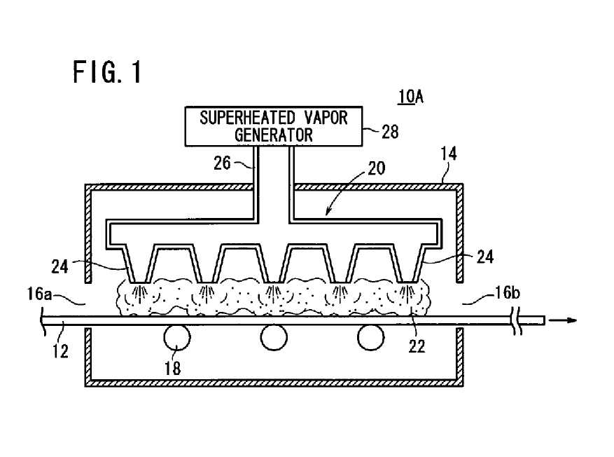

The first treatment using the superheated vapor will be described with reference to FIG. 1 below. FIG. 1 is a structural view showing an example of a first drying apparatus 10A usable in the present invention. The first drying apparatus 10A has a drying box 14 disposed along the direction of conveying a smoothed conductive film precursor 12. Slit-like openings 16a and 16b, through which the conductive film precursor 12 is transferred, are formed at both ends of the drying box 14, and a plurality of path rollers 18 for transferring the conductive film precursor 12 are disposed inside the drying box 14.

The drying box 14 contains a dryer 20 for applying a superheated vapor onto the conductive metal portion on the conductive film precursor 12, thereby drying the conductive metal portion.

The dryer 20 has a plurality of nozzles 24 for spraying the superheated vapor 22 onto the conductive metal portion on the conductive film precursor 12. The nozzles 24 are disposed in the upper part of the drying box 14, and connected by a pipe 26 to a superheated vapor generator 28. Thus, the dryer 20 can apply the superheated vapor 22 onto the conductive metal portion on the conductive film precursor 12. The number and positions of the nozzles 24 are not limited to the example of FIG. 1. The superheated vapor 22 may be a superheated water vapor or a mixture thereof with a gas.

The superheated vapor 22 is sprayed from the nozzles 24 onto the conductive metal portion on the conductive film precursor 12 for a supply time of 4 to 120 seconds. When the supply time is shorter than 4 seconds, a great conductivity improvement cannot be expected. From this viewpoint, the supply time is preferably 4 seconds or more. On the other hand, when the supply time is longer than 120 seconds, the conductivity improvement is saturated. Thus, it is wasteful to supply the superheated vapor 22 for more than 120 seconds.

The superheated vapor 22 is sprayed from the nozzles 24 onto the conductive metal portion on the conductive film precursor 12 at a supply amount of 500 to 600 g/m³. The temperature of the superheated vapor 22 is controlled at 100° C. to 160° C. at 1 atm. When the smoothed conductive metal portion is dried by spraying the superheated vapor 22 in this manner, the surface resistance of the smoothed conductive film precursor 12 can be further lowered by about 68% to 77% to largely improve the conductivity. In a case where the smoothing treatment is not carried out, the surface resistance of the conductive film precursor 12 can be lowered by about 56% to 82%.

In addition, in the first treatment, the supply time may be a short time of 4 to 120 seconds, preferably 10 to 70 seconds. Therefore, it is possible to make small the space for contact with the superheated vapor 22, so that the treatment equipment can be downsized, and the throughput can be improved.

<Second Treatment using Pressurized Vapor>

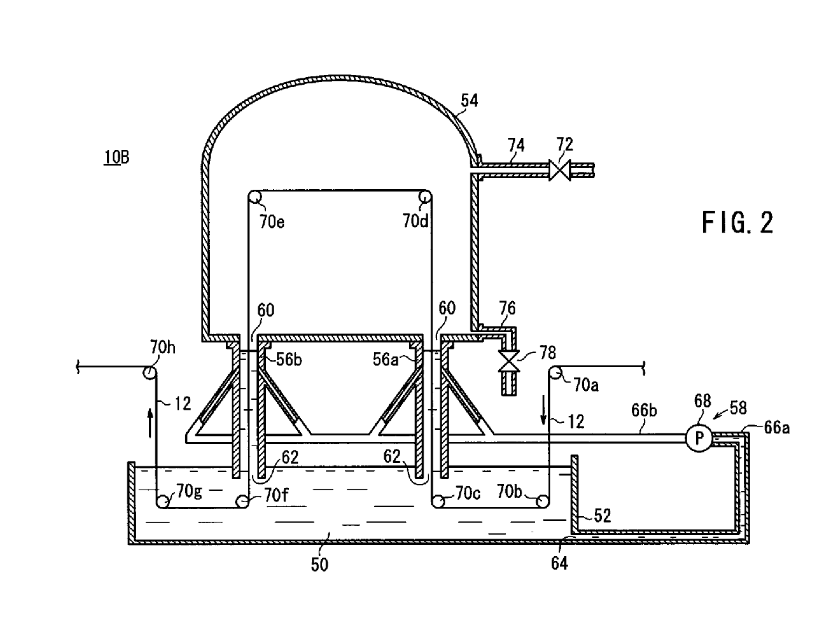

The second treatment using the pressurized vapor will be described with reference to FIG. 2 below. FIG. 2 is a structural view showing an example of a second drying apparatus 10B for use in the present invention. The second drying apparatus 10B has a structure similar to a liquid jet-type sealing apparatus described in Japanese Laid-Open Patent Publication No. 60-202049. The second drying apparatus 10B contains a liquid bath 52 for storing a liquid 50 (such as water), a high-pressure gas treatment chamber 54 disposed above the liquid bath 52, a first liquid jet part 56a and a second liquid jet part 56b placed between the liquid bath 52 and the high-pressure gas treatment chamber 54, and a circulation part 58 for circulating the liquid 50 of the liquid bath 52 into the first and second liquid jet parts 56a, 56b.

The first and second liquid jet parts 56a, 56b each have an upper slit 60 connected to a bottom opening of the high-pressure gas treatment chamber 54 and a lower slit 62 soaked in the liquid 50 in the liquid bath 52. The circulation part 58 has an outlet 64 formed on the liquid bath 52, a pressure pump 68 for transferring the liquid 50 from the outlet 64 through a first pipe 66a toward the first and second liquid jet parts 56a, 56b, and a second pipe 66b for introducing the liquid 50 from the pressure pump 68 to the first and second liquid jet parts 56a, 56b.

Then, one transfer path is formed from the liquid bath 52 through the first liquid jet part 56a, the high-pressure gas treatment chamber 54 and the second liquid jet part 56b, to the liquid bath 52. Thus, for example, first to eighth path rollers 70a to 70h are disposed for transferring the conductive film precursor 12 along the transfer path.

A high-pressure gas is introduced through a supply valve 72 and a supply pipe 74 into the high-pressure gas treatment chamber 54 by a blower (not shown). The high-pressure gas introduced into the high-pressure gas treatment chamber 54 may be partly liquefied, and the liquid is discharged through a discharge pipe 76 and a discharge valve 78. The sealing airtightness of the apparatus can be increased by appropriately controlling the pressure of high-pressure gas supplied into the high-pressure gas treatment chamber 54 and the pressure of the pressure pump 68 for circulating the liquid 50, thereby controlling the liquid levels within the first and second liquid jet parts 56a, 56b.

In this example, the high-pressure gas is a pressurized saturated water vapor. Therefore, the high-pressure gas treatment chamber 54 is filled with the pressurized saturated water vapor. Thus, when the smoothed conductive film precursor 12 is transferred by the first to eighth path rollers 70a to 70h, the conductive metal portion on the conductive film precursor 12 is brought into contact with the pressurized saturated water vapor. As a result, the surface resistance of the smoothed conductive film precursor 12 can be further lowered by about 77% to 85% to largely improve the conductivity. The saturated water vapor preferably has an absolute pressure of 101 to 361 kPaA. The conductive metal portion on the conductive film precursor 12 is preferably brought into contact with the pressurized saturated water vapor for 20 to 120 seconds.

The second drying apparatus 10B of FIG. 2 is suitable for the elongate conductive film precursor 12. In addition, in the case of using a conductive film precursor, for example, having a rectangular shape which is 60 mm long and 1 m wide, an autoclave or the like can be used for treating the precursor in a sheet-fed manner. A common autoclave has a cylindrical container and a cover for closing an upper opening of the container. An exhaust outlet, a thermometer, and a manometer are disposed on the cover, and a discharge valve is disposed on the bottom of the container. In the use of the autoclave, water is put in the container while the discharge valve is closed, the conductive film precursor is placed above the water in the container, the cover is closed, and thereafter the exhaust outlet is opened, and the container is heated. Air in the container is initially discharged from the exhaust outlet, and then steam is spouted therefrom. When the container is filled with water vapor, the exhaust outlet is closed, and the container is continuously heated while the inner temperature and pressure are controlled. The heating is stopped after a predetermined time, the container is cooled, and then the conductive film precursor is taken from the container. The heating is carried out using a gas burner, etc. Also an autoclave described in Japanese Laid-Open Patent Publication No. 06-134283 can be suitably used in this invention as well as the above common autoclave.

### [Water Washing]

In the method of the present invention, the conductive metal portion is preferably water-washed after the treatment with the superheated or pressurized vapor. A binder dissolved or embrittled by the superheated or pressurized vapor can be removed by the water washing after the vapor contact treatment, thereby to improve the conductivity. After the water washing, the conductive metal portion is dried. In this case, the drying temperature is preferably 60° C. or more, more preferably 70 to 90° C., and still more preferably 80 to 90° C. The drying after the water washing causes shrinkage of the film, and the silver density of the film is accordingly increased, whereby the conductivity thereof is improved.

### [Plating Treatment]

In the present invention, the metallic silver portion is subjected to the smoothing treatment, and may be subjected to a plating treatment. By the plating treatment, the surface resistance can be further lowered to improve the conductivity. The smoothing treatment may be carried out before or after the plating treatment. When the smoothing treatment is carried out before the plating treatment, the plating treatment can be more efficiently carried out to form a uniform plated layer. The plating treatment may be an electrolytic or electroless treatment. The material for the plated layer is preferably a metal with a sufficient conductivity such as copper.

The present invention may be appropriately combined with technologies described in the following Laid-Open

Patent Publications and International Pamphlets shown in Tables 1 and 2. “Japanese Laid-Open Patent”, “Publication No.”, “Pamphlet No.”, and the like are omitted.

TABLE 1

| | | | | |
|---|---|---|---|---|
| 2004-221564 | 2004-221565 | 2007-200922 | 2006-352073 | 2007-129205 |
| 2007-235115 | 2007-207987 | 2006-012935 | 2006-010795 | 2006-228469 |
| 2006-332459 | 2009-21153 | 2007-226215 | 2006-261315 | 2007-072171 |
| 2007-102200 | 2006-228473 | 2006-269795 | 2006-269795 | 2006-324203 |
| 2006-228478 | 2006-228836 | 2007-009326 | 2006-336090 | 2006-336099 |
| 2006-348351 | 2007-270321 | 2007-270322 | 2007-201378 | 2007-335729 |
| 2007-134439 | 2007-149760 | 2007-208133 | 2007-178915 | 2007-334325 |
| 2007-310091 | 2007-116137 | 2007-088219 | 2007-207883 | 2007-013130 |
| 2005-302508 | 2008-218784 | 2008-227350 | 2008-227351 | 2008-244067 |
| 2008-267814 | 2008-270405 | 2008-277675 | 2008-277676 | 2008-282840 |
| 2008-283029 | 2008-288305 | 2008-288419 | 2008-300720 | 2008-300721 |
| 2009-4213 | 2009-10001 | 2009-16526 | 2009-21334 | 2009-26933 |
| 2008-147507 | 2008-159770 | 2008-159771 | 2008-171568 | 2008-198388 |
| 2008-218096 | 2008-218264 | 2008-224916 | 2008-235224 | 2008-235467 |
| 2008-241987 | 2008-251274 | 2008-251275 | 2008-252046 | 2008-277428 |

TABLE 2

| | | | | |
|---|---|---|---|---|
| 2006/001461 | 2006/088059 | 2006/098333 | 2006/098336 | 2006/098338 |
| 2006/098335 | 2006/098334 | 2007/001008 | | |

### EXAMPLES

The present invention will be described more specifically below with reference to Examples. Materials, amounts, ratios, treatment contents, treatment procedures, and the like, used in Examples, may be appropriately changed without departing from the scope of the present invention. The following specific examples are, therefore, to be considered in all respects as illustrative and not restrictive.

### First Example

### Examples 1 to 15 and Reference Examples 1 to 4

### [Preparation of Emulsion]

### Liquid 1

| | |
|---|---|
| Water | 750 ml |
| Phthalated gelatin | 20 g |
| Sodium chloride | 3 g |
| 1,3-Dimethylimidazolidine-2-thione | 20 mg |
| Sodium benzenethiosulfonate | 10 mg |
| Citric acid | 0.7 g |

### Liquid 2

| | |
|---|---|
| Water | 300 ml |
| Silver nitrate | 150 g |
| Liquid 3 | |
| Water | 300 ml |
| Sodium chloride | 38 g |
| Potassium bromide | 32 g |
| Potassium hexachloroiridate (III) | 5 ml |
| (0.005% KCl, 20% aqueous solution) | |
| Ammonium hexachlororhodate | 7 ml |
| (0.001% NaCl, 20% aqueous solution) | |

The potassium hexachloroiridate (III) (0.005% KCl, 20% aqueous solution) and the ammonium hexachlororhodate (0.001% NaCl, 20% aqueous solution) in Liquid 3 were prepared by dissolving a complex powder in a 20% aqueous solution of KCl or NaCl and by heating the resultant solution at 40° C. for 120 minutes respectively.

Liquid 1 was maintained at 38° C. and pH 4.5, and 90% of Liquids 2 and 3 were simultaneously added to Liquid 1 over 20 minutes under stirring to form 0.16-μm nuclear particles. Then, Liquids 4 and 5 described below were added thereto over 8 minutes, and residual 10% of Liquids 2 and 3 were added over 2 minutes, so that the nuclear particles were grown to 0.21 μm. Further 0.15 g of potassium iodide was added, and the resulting mixture was ripened for 5 minutes, whereby the particle formation was completed.

### Liquid 4

| | |
|---|---|
| Water | 100 ml |
| Silver nitrate | 50 g |
| Liquid 5 | |
| Water | 100 ml |
| Sodium chloride | 13 g |
| Potassium bromide | 11 g |
| Yellow prussiate of potash | 5 mg |

The resultant was water-washed by a common flocculation method. Specifically, the temperature was lowered to 35° C., the pH was lowered by sulfuric acid until the silver halide was precipitated (within a pH range of 3.6±0.2), and about 3 L of the supernatant solution was removed (first water washing). Further, 3 L of a distilled water was added thereto, sulfuric acid was added until the silver halide was precipitated, and 3 L of the supernatant solution was removed again (second water washing). The procedure of the second water washing was repeated once more (third water washing), whereby the water washing and demineralization process was completed. After the water washing and demineralization process, the obtained emulsion was controlled at a pH of 6.4 and a pAg of 7.5. 100 mg of a stabilizer of 1,3,3a,7-tetraazaindene and 100 mg of an antiseptic agent of PROXEL (trade name, available from ICI Co., Ltd.) were added thereto, to obtain a final emulsion of cubic silver iodochlorobromide particles, which contained 70 mol % of silver chloride and 0.08 mol % of silver iodide, and had an average particle diameter of 0.22 μm and a variation coefficient of 9%. The final emulsion had a pH of 6.4, pAg of 7.5, conductivity of 4000 μS/cm, density of 1.4×10³ kg/m³, and viscosity of 20 mPa·s.

### [Production of Coating Sample]

8.0×10⁻⁴ mol/mol Ag of the following compound (Cpd-1) and 1.2×10⁻⁴ mol/mol Ag of 1,3,3a,7-tetraazaindene were added to the emulsion, and the resultant was well mixed. Then, the following compound (Cpd-2) was added to the mixture to control the swelling ratio if necessary, and the pH of the coating liquid was controlled to 5.6 using citric acid.

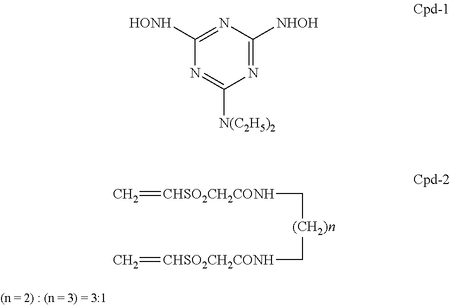

An undercoat layer was formed on a 100-μm-thick polyethylene terephthalate (PET), and the emulsion layer coating liquid prepared from the above emulsion was applied to the undercoat layer at an Ag density of 5 g/m² and a gelatin density of 0.4 g/m². The resultant was dried to obtain a coating sample.

In the obtained coating sample, the emulsion layer had a silver/binder volume ratio (silver/GEL ratio (vol)) of 1/1.

### [Exposure and Development]

The dried coating was exposed to a parallel light from a light source of a high-pressure mercury lamp, through a photomask having a lattice-patterned space (line/space=195 μm/5 μm (pitch 200 μm)). The photomask was capable of forming a patterned developed silver image (line/space=5 μm/195 μm). Then the coating was subjected to a treatment containing development, fixation, water washing, and drying.

### (Developer Composition)

1 L of the developer contained the following compounds.

| | |
|---|---|
| Hydroquinone | 15 g/L |
| Sodium sulfite | 30 g/L |
| Potassium carbonate | 40 g/L |
| Ethylenediamine tetraacetate | 2 g/L |
| Potassium bromide | 3 g/L |
| Polyethylene glycol 2000 | 1 g/L |
| Potassium hydroxide | 4 g/L |
| pH | Controlled at 10.5 |

### (Fixer Composition)

1 L of the fixer contained the following compounds.

| | |
|---|---|
| Ammonium thiosulfate (75%) | 300 ml |
| Ammonium sulfite monohydrate | 25 g/L |
| 1,3-Diaminopropane tetraacetate | 8 g/L |
| Acetic acid | 5 g/L |
| Aqueous ammonia (27%) | 1 g/L |
| Potassium iodide | 2 g/L |
| pH | Controlled at 6.2 |

### [Reduction Treatment]

The above developed sample was dipped in a 10 wt % aqueous sodium sulfite solution kept at 40° C. for 10 minutes.

### [Calender Treatment]

The above developed sample (the conductive film precursor) was subjected to a calender treatment using a pair of metal rolls as calender rolls. The sample was transferred between the metal rolls at a line pressure of 4900 N/cm (500 kgf/cm) to perform a calender treatment. The surface resistance of the calender-treated sample was then measured. The surface resistance values of 10 areas optionally selected in the sample were measured by LORESTA GP (Model No. MCP-T610) manufactured by Dia Instruments Co., Ltd. utilizing an in-line four-probe method (ASP), and the average of the measured values was used as the surface resistance of the sample. The surface resistance of the sample was 2.5 Ω/sq.

### Example 1

The calender-treated sample (the conductive film precursor) was brought into contact with a superheated vapor using the first drying apparatus 10A of FIG. 1, and then water-washed. The superheated vapor had a temperature of 105° C. and was supplied at an amount of 590 g/m³. The treatment time, for which the sample was in contact with the superheated vapor, was 10 seconds.

### Examples 2 to 5

In Examples 2, 3, 4 and 5, the samples were brought into contact with the superheated vapor and water-washed in the same manner as Example 1 except for using treatment times of 20, 40, 60 and 70 seconds respectively.

### Example 6

In Example 6, the sample was brought into contact with the superheated vapor and water-washed in the same manner as Example 1 except that the superheated vapor had a temperature of 121° C. and was supplied at an amount of 540 g/m³.

### Examples 7 to 10

In Examples 7, 8, 9 and 10, the samples were brought into contact with the superheated vapor and water-washed in the same manner as Example 6 except for using treatment times of 20, 40, 60 and 70 seconds respectively.

### Example 11

In Example 11, the sample was brought into contact with the superheated vapor and water-washed in the same manner as Example 1 except that the superheated vapor had a temperature of 150° C. and was supplied at an amount of 506 g/m³.

### Examples 12 to 15

In Examples 12, 13, 14 and 15, the samples were brought into contact with the superheated vapor and water-washed in the same manner as Example 11 except for using treatment times of 20, 40, 60 and 70 seconds respectively.

### Reference Example 1

The calender-treated sample (the conductive film precursor) was brought into contact with a saturated water vapor and then water-washed. The saturated water vapor had a temperature of 97° C. The treatment time, for which the sample was in contact with the saturated water vapor, was 20 seconds.

### Reference Examples 2 to 4

In Reference Examples 2, 3 and 4, the samples were brought into contact with the saturated water vapor and water-washed in the same manner as Reference Example 1 except for using treatment times of 40, 60 and 70 seconds respectively.

### [Evaluation]

In each sample of Examples 1 to 15 and Reference Examples 1 to 4, the surface resistance values of optionally selected 10 areas were measured by LORESTA GP (Model No. MCP-T610) manufactured by Dia Instruments Co., Ltd. utilizing an in-line four-probe method (ASP), and the average of the measured values was used as the surface resistance of each sample. The measurement results of Examples 1 to 15 and Reference Examples 1 to 4 are shown in Table 3 with details.

TABLE 3

| | | Supply | Treatment | Surface |
|---|---|---|---|---|
| | Temperature | amount | time | resistance |
| | (° C.) | (g/m³) | (sec) | (Ω/sq.) |
| Reference | 97 | 615 | 20 | 0.79 |
| Example 1 | | | | |
| Reference | 97 | 615 | 40 | 0.68 |
| Example 2 | | | | |
| Reference | 97 | 615 | 60 | 0.61 |
| Example 3 | | | | |
| Reference | 97 | 615 | 70 | 0.60 |
| Example 4 | | | | |
| Example 1 | 105 | 590 | 10 | 0.82 |
| Example 2 | 105 | 590 | 20 | 0.69 |
| Example 3 | 105 | 590 | 40 | 0.64 |
| Example 4 | 105 | 590 | 60 | 0.59 |
| Example 5 | 105 | 590 | 70 | 0.58 |
| Example 6 | 121 | 540 | 10 | 0.79 |
| Example 7 | 121 | 540 | 20 | 0.64 |
| Example 8 | 121 | 540 | 40 | 0.60 |
| Example 9 | 121 | 540 | 60 | 0.58 |
| Example 10 | 121 | 540 | 70 | 0.58 |
| Example 11 | 150 | 506 | 10 | 0.80 |
| Example 12 | 150 | 506 | 20 | 0.62 |
| Example 13 | 150 | 506 | 40 | 0.59 |
| Example 14 | 150 | 506 | 60 | 0.58 |
| Example 15 | 150 | 506 | 70 | 0.57 |

The calender-treated sample (the conductive film precursor) had a surface resistance of about 2.5 Ω/sq. In Examples 1, 6 and 11, the surface resistances were lowered by about 68% to 0.82, 0.79 and 0.80 Ω/sq respectively, simply by bringing the calender-treated sample into contact with the superheated vapor for the short time of only 10 seconds. Also, in Examples 2, 7 and 12, simply by bringing the sample into contact with the superheated vapor for the short time of only 20 seconds, the surface resistances were further lowered by 0.13, 0.15 and 0.18 Ω/sq respectively, as compared with Examples 1, 6 and 11 using the treatment time of 10 seconds. That is, the surface resistances were lowered by about 75% relative to the surface resistance of the calender-treated sample. Thus, it is clear that the surface resistance of the calender-treated sample (the conductive film precursor) was largely lowered simply by bringing the sample into contact with the superheated vapor for the short time of only 10 or 20 seconds, thereby to improve the conductivity. Furthermore, in Examples 4, 5, 9, 10, 14 and 15, the surface resistances were lowered by about 76% to 77% with respect to the surface resistance of the calender-treated sample simply by bringing the calender-treated sample into contact with the superheated vapor for 60 or 70 seconds. In addition, also in the case of using a silver/binder volume ratio of 1.5/1, 2/1 or 3/1 for the emulsion layer in Examples 1 to 15, the conductivity was improved in the same manner as described above.

In Reference Examples 1 to 4, the calender-treated samples were in contact with the saturated water vapor at 97° C. for the treatment time of 10 to 40 seconds. From the comparison between Reference Examples 1 to 4 and Examples 1 to 15, the saturated water vapor was slightly inferior in the surface resistance lowering to the superheated vapor.

### Second Example

### <Examples 21 to 25 and Reference Examples 11 to 14

The conductive film precursor was prepared in the same manner as Example 1 except for not performing the calender treatment, and the surface resistance thereof was measured. As a result, the conductive film precursor had a surface resistance of 35 Ω/sq.

### Example 21

The non-calender-treated sample (the conductive film precursor) was brought into contact with a superheated vapor using the first drying apparatus 10A of FIG. 1, and then water-washed. The superheated vapor had a temperature of 121° C. and was supplied at an amount of 540 g/m³. The treatment time, for which the sample was in contact with the superheated vapor, was 10 seconds.

### Examples 22 to 25

In Example 22, 23, 24 and 25, the samples were brought into contact with the superheated vapor and water-washed in the same manner as Example 21 except for using treatment times of 20, 40, 60 and 70 seconds respectively.

### Reference Example 11

The non-calender-treated sample (the conductive film precursor) was brought into contact with a saturated water vapor and then water-washed. The saturated water vapor had a temperature of 97° C. The treatment time, for which the sample was in contact with the saturated water vapor, was 20 seconds.

### Reference Examples 12 to 14

In Reference Examples 12, 13 and 14, the samples were brought into contact with the saturated water vapor and water-washed in the same manner as Reference Example 11 except for using treatment times of 40, 60 and 70 seconds respectively.

### [Evaluation]

The surface resistances of Examples 21 to 25 and Reference Examples 11 to 14 were measured. The measurement results are shown in Table 4 with details.

TABLE 4

| | | Supply | Treatment | Surface |
|---|---|---|---|---|
| | Temperature | amount | time | resistance |
| | (° C.) | (g/m³) | (sec) | (Ω/sq.) |
| Reference | 97 | 615 | 20 | 2.13 |
| Example 11 | | | | |
| Reference | 97 | 615 | 40 | 1.30 |
| Example 12 | | | | |
| Reference | 97 | 615 | 60 | 1.25 |
| Example 13 | | | | |
| Reference | 97 | 615 | 70 | 1.25 |
| Example 14 | | | | |
| Example 21 | 121 | 540 | 10 | 2.20 |
| Example 22 | 121 | 540 | 20 | 1.25 |
| Example 23 | 121 | 540 | 40 | 1.10 |
| Example 24 | 121 | 540 | 60 | 0.90 |
| Example 25 | 121 | 540 | 70 | 0.90 |

The non-calender-treated sample (the conductive film precursor) had a surface resistance of about 35 Ω/sq. In Example 21, the surface resistance was lowered by about 94% to 2.20 Ω/sq simply by bringing the non-calender-treated sample into contact with the superheated vapor for the short time of only 10 seconds. In Example 22, simply by bringing the sample into contact with the superheated vapor for the short time of only 20 seconds, the surface resistance was further lowered by 0.95 Ω/sq, as compared with Example 21 using the treatment time of 10 seconds. That is, the surface resistance was lowered by about 96% with respect to the surface resistance of the non-calender-treated conductive film precursor. Thus, it is clear that the surface resistance of the non-calender-treated sample (the conductive film precursor) was largely lowered simply by bringing the sample into contact with the superheated vapor for the short time of only 10 or 20 seconds, thereby to improve the conductivity. Furthermore, in Examples 24 and 25, the surface resistance was lowered by about 97% with respect to the surface resistance of the non-calender-treated sample simply by bringing the non-calender-treated sample into contact with the superheated vapor for 60 or 70 seconds. In addition, also in the case of using a silver/binder volume ratio of 1.5/1, 2/1 or 3/1 for the emulsion layer in Examples 21 to 25, the conductivity was improved in the same manner as described above.

In Reference Examples 11 to 14, the non-calender-treated sample was in contact with the saturated water vapor at 97° C. for the treatment time of 10 to 40 seconds. From the comparison between Reference Examples 11 to 14 and Examples 21 to 25, the saturated water vapor was slightly inferior in the surface resistance lowering to the superheated vapor.

### Third Example

### Examples 31 to 34

The surface resistance of the calender-treated sample (the conductive film precursor) prepared in the same manner as Example 1 was measured. As a result, the sample had a surface resistance of 2.5 Ω/sq.

### Example 31

The calender-treated sample (the conductive film precursor) was brought into contact with a pressurized water vapor using the second drying apparatus 10B of FIG. 2, and then water-washed. The pressurized water vapor had a pressure of 101.4180 kPaA. The treatment time, for which the sample was in contact with the pressurized water vapor, was 60 seconds.

### Examples 32 to 34

In Examples 32, 33 and 34, the samples were brought into contact with the pressurized water vapor and water-washed in the same manner as Example 31 except for using pressures of 143.3760, 169.1770 and 205.0389 kPaA respectively.

### [Evaluation]

The surface resistances of Examples 31 to 34 were measured. The measurement results are shown in Table 5 with details.

TABLE 5

| | | Treatment | Surface |
|---|---|---|---|
| | Pressure | time | resistance |
| | (kPaA) | (sec) | (Ω/sq.) |
| Example 31 | 101.4180 | 60 | 0.58 |
| Example 32 | 143.3760 | 60 | 0.52 |
| Example 33 | 169.1770 | 60 | 0.45 |
| Example 34 | 205.0389 | 60 | 0.39 |

The calender-treated sample (the conductive film precursor) had a surface resistance of about 2.5 Ω/sq. In Example 31, 32, 33 and 34, the surface resistances were lowered by about 77% to 85% to 0.58, 0.52, 0.45 and 0.39 Ω/sq respectively simply by bringing the calender-treated sample into contact with the pressurized water vapor having a high pressure of 0.1 MPa or more for 60 seconds. Thus, it is clear that the surface resistance of the calender-treated sample (the conductive film precursor) was largely lowered simply by bringing the sample into contact with the pressurized vapor for 60 seconds, thereby to improve the conductivity. In addition, also in the case of using a silver/binder volume ratio of 1.5/1, 2/1 or 3/1 for the emulsion layer in Examples 31 to 34, the conductivity was improved in the same manner as described above.

It is to be understood that the conductive film producing method of the present invention is not limited to the above embodiments, and various changes and modifications may be made therein without departing from the scope of the present invention.

What is claimed is:

1. A method for producing a conductive film, comprising
a conductive metal portion forming step of forming a conductive metal portion containing a conductive substance and a binder on a support,
a smoothing treatment step of smoothing the conductive metal portion, and
a vapor contact step of bringing the smoothed conductive metal portion into contact with a saturated vapor (a pressurized vapor) at a pressure higher than 0.1 MPa, wherein
the saturated vapor has an absolute pressure of 101 to 361 kPaA.

2. A method according to claim 1, wherein the smoothed conductive metal portion is brought into contact with the pressurized vapor for 5 minutes or less.

3. A method according to claim 1, wherein the smoothed conductive metal portion is brought into contact with the pressurized vapor for 20 to 120 seconds.

4. A method according to claim 1, wherein in the conductive metal portion forming step, an emulsion layer containing a silver salt is formed on the support to prepare a photosensitive material, and thereafter the photosensitive material is exposed and developed to form the conductive metal portion on the support.

5. A method according to claim 1, wherein in the conductive metal portion forming step, a paste containing the conductive substance and the binder is printed on the support to form the conductive metal portion on the support.

6. A method according to claim 1, wherein in the smoothing treatment step, the conductive metal portion is smoothed under a line pressure of 1960 N/cm (200 kgf/cm) or more.
